(19) United States
(12) Patent Application Publication
(10) Pub. No.: US 2025/0096056 A1
(43) Pub. Date: Mar. 20, 2025

(54) ENCAPSULANT WITH POROUS COLORANT FOR ELECTRONIC PACKAGE

(71) Applicant: Infineon Technologies AG, Neubiberg (DE)

(72) Inventors: Yosephine ANDRIANI, Semarang (ID); Stefan SCHWAB, Wald (DE)

(73) Assignee: Infineon Technologies AG, Neubiberg (DE)

(21) Appl. No.: 18/828,836

(22) Filed: Sep. 9, 2024

(30) Foreign Application Priority Data
Sep. 19, 2023 (DE) 10 2023 209 092.9

(51) Int. Cl. H01L 23/29; C08K 9/04; C09D 7/62; C09D 163/00; C09D 183/04

(52) U.S. Cl. CPC H01L 23/295; C09D 7/62; C09D 163/00; C09D 183/04; C08K 9/04

(57) ABSTRACT

An encapsulant for an electronic package is disclosed. In one example, the encapsulant comprises an electrically insulating matrix material, and a porous colorant in the matrix material.

### CROSS-REFERENCE TO RELATED APPLICATION

This Utility patent application claims priority to German Patent Application No. 10 2023 209 092.9 filed Sep. 19, 2023, which is incorporated herein by reference.

### BACKGROUND

### Technical Field

Various embodiments relate generally to an encapsulant, a package, and a manufacturing method.

### Description of the Related Art

A conventional package may comprise a semiconductor component mounted on a carrier such as a leadframe structure, may be electrically connected by a bond wire extending from the semiconductor component to the carrier, and may be molded using a mold compound as an encapsulant.

Electric reliability of such a package may be an issue.

### SUMMARY

There may be a need for a package with high electric reliability.

According to an exemplary embodiment, an encapsulant for an electronic package is provided, wherein the encapsulant comprises an electrically insulating matrix material, and a porous colorant in the matrix material.

According to another exemplary embodiment, a package is provided which comprises a carrier, an electronic component mounted on the carrier, and an encapsulant having the above mentioned features at least partially encapsulating the electronic component and the carrier.

According to another exemplary embodiment, a method of manufacturing an encapsulant for an electronic package is provided, wherein the method comprises providing an electrically insulating matrix material, and inserting a porous colorant in the matrix material.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates an encapsulant according to an exemplary embodiment.

FIG. 2 illustrates a flowchart of a method of manufacturing an encapsulant according to an exemplary embodiment.

FIG. 3 illustrates a cross-sectional view of a package according to an exemplary embodiment.

FIG. 4 illustrates a cross-sectional view of a package according to another exemplary embodiment.

### DETAILED DESCRIPTION

There may be a need for a package with high electric reliability.

According to an exemplary embodiment, an encapsulant for an electronic package is provided, wherein the encapsulant comprises an electrically insulating matrix material, and a porous colorant in the matrix material.

According to another exemplary embodiment, a package is provided which comprises a carrier, an electronic component mounted on the carrier, and an encapsulant having the above mentioned features at least partially encapsulating the electronic component and the carrier.

According to another exemplary embodiment, a method of manufacturing an encapsulant for an electronic package is provided, wherein the method comprises providing an electrically insulating matrix material, and inserting a porous colorant in the matrix material.

According to an exemplary embodiment, an encapsulant (for example a mold compound) for encapsulating an electronic package (in particular for encapsulating an electronic component mounted on a carrier) is provided. A matrix material may form the basis of the encapsulant and may be electrically insulating to thereby avoid undesired current flow between an exterior and an interior of the encapsulant (for example towards and/or from an encapsulated electronic component of a corresponding package). Highly advantageously, a porous colorant with a large pore density may be included in or embedded in the matrix material. Thanks to its many pores leading to a significantly increased surface area per volume ratio compared to non-porous colorant, such a porous colorant may show excellent electrically insulating properties and may therefore promote electrical reliability of the package. This reliable electric insulation property is in contrast to conventional approaches, in which only electrically conductive carbon black is used as a colorant of encapsulant. Without wishing to be bound to a specific theory, it is presently believed that a porous colorant providing an extremely high surface area thanks to its pores leads to its highly pronounced electric insulation properties. At the same time, such a porous colorant may provide the encapsulant with a defined color (such as black or dark gray). This may bring advantages in terms of laser markability, and may lead to a simplification of a package stress test which can be executed without or at least without significant color change. Moreover, the porous colorant of the encapsulant, which may be depleted or even entirely free of electrically conductive particles (such as carbon black, metallic particles, etc.), may result in an improved breakdown voltage and an improved long-term low voltage stability. At the same time, a low amount of or even absent electrically conductive particles in the encapsulant may advantageously reduce the tendency of corrosion and may improve adhesion of the constituents (such as an electronic component and/or a carrier) in contact with the encapsulant. The reduced tendency of corrosion may be associated with the colorant's high surface area that can adsorb free ions and/or small molecules. In particular, an excellent time-dependent dielectric breakdown (TDDB) behavior may be obtained with such an encapsulant.

### DESCRIPTION OF FURTHER EXEMPLARY EMBODIMENTS

In the following, further exemplary embodiments of the encapsulant, the package, and the method will be explained.

In the context of the present application, the term “encapsulant” may particularly denote a material, structure or member surrounding or intended for surrounding at least part of an electronic component and at least part of a carrier of a package. In this context, an encapsulant may provide mechanical protection and electrical insulation, and optionally a contribution to heat removal during operation. In particular, said encapsulant may be electrically insulating, for instance a mold compound. A mold compound may comprise a matrix of flowable and hardenable material, in particular a colorant, optionally one or more additives, and optionally filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel).

In the context of the present application, the term “encapsulant for electronic package” may particularly denote that the encapsulant is suitable and configured for encapsulating one or more constituents of an electronic package, in particular an electronic component and/or a carrier. This may require in particular a sufficient electric insulation of the encapsulant for preventing flow of electric current through the encapsulant. Furthermore, this may require a proper adhesion of the encapsulant with one or more constituents of the package (in particular an electronic component and/or a carrier), which may be accomplished by a porous colorant, an appropriate matrix material and/or one or more appropriate additives of the encapsulant.

In the context of the present application, the term “electrically insulating matrix material” may in particular denote a material in which the porous colorant is embedded. The electrically insulating properties of the matrix material may be so pronounced that no noteworthy amount of electric current may flow through or along the encapsulant. Said matrix material may comprise a resin, in particular a polymer resin. For example, such a polymer resin may be an epoxy resin. For instance, the matrix material may be made of a curable material such as epoxy resin which may be hardened during an encapsulation process. Filler particles inside of said matrix material may fine-tune the package properties.

In the context of the present application, the term “colorant” may in particular denote an agent providing the encapsulant with a predefined and durable color. Preferably, said color is black or dark gray.

In the context of the present application, the term “porous colorant” may in particular denote a colorant which comprises a large plurality of pores. More particularly, the porous colorant may be formed as a large plurality of particles, at least a majority of which comprising one or more pores. The pores of the porous colorant may comprise through pores extending entirely through a colorant particle, blind pores extending into and ending inside of a colorant particle, and/or bifurcated pores forming part of an interconnected pore network inside of a respective colorant particle.

In the context of the present application, the term “package” may particularly denote an electronic device which may comprise one or more electronic components mounted on a (in particular partially or entirely electrically conductive) carrier. Said constituents of the package may be encapsulated at least partially by an encapsulant. Optionally, one or more electrically conductive connection elements (such as metallic pillars, pumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support for the electronic component(s) to be mounted thereon, and which may also contribute to the electric interconnection between the electronic component(s) and the periphery of the package. In other words, the carrier may fulfil a mechanical support function and optionally an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate. Also at least part of the carrier may be encapsulated by the encapsulant, together with the electronic component.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof. The electronic component may be a bare die or may be already packaged or encapsulated. Semiconductor chips implemented according to exemplary embodiments may be formed in silicon technology, gallium nitride technology, silicon carbide technology, etc.

In an embodiment, the matrix material comprises an epoxy resin, silicone, a bismalcimide and/or an imide. Epoxy resin may be an appropriate matrix material for an epoxy mold compound (EMC). Silicone may form the basis of a gel-type encapsulant for potting.

In an embodiment, the encapsulant is configured as a mold compound, in particular as an epoxy-based mold compound. Thus, different mold compound types may be used, such as silicone mold compound, bismaleimide mold compound, imide mold compound, etc. Molding may denote a manufacturing process of shaping liquid or pliable raw material using a rigid tool called a mold. Hence, encapsulation of the one or more semiconductor components of the semiconductor package may be accomplished by molding. Consequently, the encapsulant may comprise a curable matrix (for instance on the basis of epoxy resin) with filler particles (for fine-tuning encapsulant functions) therein. By implementing a porous colorant in the mold compound, a further improved electric reliability of the obtained molded semiconductor package may be achieved.

In an embodiment, the encapsulant is configured as a potting compound, in particular as a silicone gel-based compound. In particular, potting may denote a process of filling an electronic assembly with a solid or gelatinous compound, for example for high voltage assemblies. This may suppress or exclude gaseous phenomena such as corona discharge, may be done for resistance to shock and vibration, and/or may be executed for the exclusion of water, moisture, etc. When embedding porous colorant in a potting compound, electric reliability of the obtained encapsulated semiconductor package may be further improved.

In an embodiment, the porous colorant comprises porous activated carbon. Porous activated carbon may denote a carbon material (for instance formed based on carbon black, charcoal, wood or another natural material comprising carbon) which may be provided in form of particles each having a porous solid body with interior pores. Pores may be formed by a surface treatment of carbon containing particles or bodies, for instance by a treatment with a chemical, a plasma and/or a thermal treatment. Activating carbon may include forming pores or enhancing porosity in a carbon containing material.

In an embodiment, the porous colorant comprises porous titanium dioxide. Also titanium dioxide functions as a colorant by providing the encapsulant with a defined and durable color and can be treated to have pronounced porosity.

In an embodiment, the encapsulant additionally comprises carbon black and/or crystalline petroleum coke. In the context of the present application, the term “carbon black” may in particular denote a fine carbon powder which may be made by burning hydrocarbons in insufficient air. More specifically, carbon black may denote a material which may be produced by the incomplete combustion of coal and coal tar, vegetable matter, or petroleum products, including fuel oil, fluid catalytic cracking tar, and ethylene cracking in a limited supply of air. Carbon black may be a black, finely divided form of amorphous carbon. The mentioned particles provide a certain electric conductivity for removing charge carriers from the package. However, the electric conductivity of the mentioned materials is not excessively high. In the context of the present application, the term “crystalline petroleum coke” may in particular denote a material produced (for example exclusively) from fluid catalytic cracking decant oil or coal tar pitch.

Adding a limited amount of carbon black (and/or crystalline petroleum coke) to the porous colorant and the matrix material may bring the advantage of a further improved color intensity.

In an embodiment, a ratio between an amount, in weight percent, of the porous colorant and an amount, in weight percent, of the carbon black and/or the crystalline petroleum coke is in a range from 1:4 to 4:1, in particular is in a range from 1:2 to 2:1. For example, a partial weight percentage of the porous colorant may be in a range from 20 weight percent to 80 weight percent, in relation to the entire weight of the overall colorant. Correspondingly, a partial weight percentage of the carbon black (and/or the crystalline petroleum coke) may be in a range from 20 weight percent to 80 weight percent, in relation to the entire weight of the overall colorant. Of course, the different colorant constituents will always sum up to 100 weight percent of the overall colorant. The ratio between porous colorant and carbon black/crystalline petroleum coke may be used as a design parameter for a tradeoff between electric isolation properties and color intensity.

In another embodiment, the encapsulant is free of carbon black and/or is free of crystalline petroleum coke. In particular, the encapsulant may be free of electrically conductive particles (such as carbon black). A skilled person will understand that an encapsulant being free of electrically conductive particles may still have an unavoidable residue of electrically conductive particles due to manufacturing tolerances and the like. Being substantially free of electrically conductive particles, the encapsulant may have an excellent electric breakdown voltage and an advantageous TDDB behavior.

In an embodiment, the porous colorant is configured as ion getter. Thus, free ions in the encapsulant, which may provide undesired electric conductivity, may be captured by the porous colorant when configured as ion getter. For configuring the porous colorant as ion getter, appropriate chemical groups may be added to the particles of the porous colorant. This may be accomplished by a chemical treatment of said particles.

In an embodiment, the porous colorant comprises at least one ion adsorbing group (or ion getting group), configured for adsorbing ions. In particular, suitable ion adsorbing groups are a carboxylic acid, a lactone, a phenol, a lactol, and/or a carboxylic anhydride.

In an embodiment, an amount of the porous colorant is at least 0.5 weight percent, in relation to the entire weight of the encapsulant, in particular is in a range from 0.5 weight percent to 2 weight percent, in relation to the entire weight of the encapsulant. Selecting the weight percentage of the porous colorant in the mentioned range may allow to keep the manufacturing effort low while simultaneously ensuring a sufficiently dark color intensity and beneficial electric properties.

In an embodiment, the porous colorant has an electric conductivity of not more than 10⁻³ S/cm, in particular not more than 10⁻⁵ S/cm. These values of the electric conductivity of the porous colorant are indicative of a highly reliable electric isolation provided by the porous colorant in combination with the electrically insulating matrix material. This is a consequence of a sufficiently high porosity of the porous colorant.

In an embodiment, the porous colorant is configured for forming carbon-oxygen complexes when in use. In order to provide this effect, carbon material of the porous colorant may be configured to show high chemisorption of oxygen.

In an embodiment, the porous colorant has a low nitrogen doping and/or a low graphitization degree. Also these properties are advantageous for the porous colorant and the correspondingly formed encapsulant.

In an embodiment, the porous colorant (in particular in form of particles) has a surface area to mass ratio of at least 100 m²/g, in particular a surface area to mass ratio in a range from 100 m²/g to 2000 m²/g, more particularly in a range from 500 m²/g to 1750 m²/g, preferably in a range from 1000 m²/g to 1500 m²/g. The mentioned values and ranges indicate a very large exterior and/or interior surface of porous colorant particles thanks to their correspondingly high density of pores. Advantageously, a large exterior surface of the porous colorant particles translates into a strong electric isolation property thereof.

In an embodiment, particles of the porous colorant have a size in a range from 0.1 μm to 100 μm. In this range, a particularly high amount of the porous exterior surface may be obtained. Preferably, an activated porous carbon particle size may be not more than 100 μm.

In an embodiment, the method comprises subjecting the porous colorant to an additional surface activating process for changing chemical groups on its surface. Hence, the already porous colorant may be subjected to an additional surface activation for further improving the contribution of the surface activated porous colorant to electric reliability of the encapsulant. This may be achieved by changing the chemical surface of the porous colorant due to the activating treatment. Additionally or alternatively, this may be achieved by enhancing porosity of the porous colorant due to the activating treatment.

In an embodiment, the method comprises treating the porous colorant by steam processing, oxidizing, corona treatment and/or a chemical treatment. Other processes for pore formation, enhancing porosity, changing the chemical surface of the porous colorant and/or surface activation may be executed as well.

In an embodiment, the method comprises treating the porous colorant for reducing its electric conductivity. In particular, increasing the porosity may reduce electric conductivity. Another target to be achieved by the treatment of the porous colorant may be an increase of its adhesion with respect to other package constituents, such as a semiconductor chip and/or a leadframe.

In an embodiment, the encapsulant further comprises filler particles in the matrix material. In the context of the present application, the term “filler particles” may particularly denote a (in particular powderous or granulate-type) substance filling out interior volumes in a surrounding medium such as a matrix. By the selection of the filler particles, the physical and/or chemical properties of the encapsulant can be adjusted. Such properties may include the coefficient of thermal expansion, the thermal conductivity, the dielectric properties, etc. The filler particles may thus be added so as to fine tune the physical, chemical, etc., properties of the encapsulant. For instance, the filler particles may increase thermal conductivity of the encapsulant so as to efficiently remove heat out of an interior of an electronic device such as a package (such heat may be generated by a semiconductor component, for instance when embodied as power semiconductor chip). It is also possible that the filler particles provide an improved dielectric decoupling between such a semiconductor component and the surrounding of the package.

In an embodiment, filler particles are selected from a group consisting of crystalline silica, fused silica, spherical silica, aluminium hydroxide, magnesium hydroxide, zirconium dioxide, calcium carbonate, calcium silicate, talc, clay, carbon fiber, glass fiber and mixtures thereof. Other filler materials are however possible depending on the demands of a certain application. Filler particles (for example SiO₂, Al₂O₃, Si₃N₄, BN, AlN, diamond, etc.), for instance for improving thermal conductivity may be used as well. In particular, organic particles may be used as fillers (for instance, fillers can also comprise or consist of polymers or polymer mixtures, such as: epoxies, polyethylene, polypropylene, etc.). In particular, filler particles may be provided as nanoparticles or microparticles. Filler particles may have identical dimensions or may be provided with a distribution of particle sizes. Such a particle size distribution may be preferred since it may allow for an improved filling of gaps in an interior of the encapsulant. For instance, the shape of the filler particles may be randomly, spherical, cuboid-like, flake-like, and film-like. The filler particles can be modified, coated, and/or treated as to improve the adhesion and/or the chemical binding to the surrounding matrix. Examples are silanes. A coating can also change the surface energy of the fillers.

In an embodiment, the electronic component is a semiconductor power chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package is a power package. In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user-convenient.

In an embodiment, the package comprises a plurality of semiconductor components encapsulated by the semiconductor package encapsulant. Thus, the package may comprise one or more semiconductor components (for instance at least one passive component, such as a capacitor, and at least one active component).

As substrate or wafer forming the basis of the semiconductor component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Carbon black is a common additive in an epoxy molding compound formulation. Carbon black imparts a stable black color to packages, provides electrostatic discharge (ESD) protection and improves the laser marking legibility.

However, excessive concentration of carbon black in an epoxy mold compound (EMC) increases the risk of package failure under high voltage conditions. Carbon black tends to aggregate and form a conductive bridge. Carbon black may shorten the distance between metals with opposing potentials and may distort the electrical field in a package.

Conventional solutions to tackle the mentioned shortcomings are to add additives, improve filler/epoxy interfacial bond, use smaller filler size as crack pinner or deflector at the expense of additional effort and change in EMC properties. For example, improving filler/epoxy interfacial bond by incorporating a surface modifier may improve the TDDB performance, but it makes the molding process harder.

In order to overcome at least part of the mentioned and/or other conventional shortcomings, an exemplary embodiment provides an encapsulant (such as a mold compound or a potting gel) being suitable for encapsulating an electronic package, which may comprise a semiconductor chip to be encapsulated. An electrically insulating matrix material (which may be provided on the basis of epoxy resin and/or silicone) may form the basis of the encapsulant and may contribute to mechanical integrity and electric isolation of package constituents. Advantageously, a colorant for coloring the encapsulant may be embodied as a porous colorant. To put it shortly, the pore structure of such a colorant may lead to a huge surface area, preferably above 200 m²/g. It has been found that such a porous colorant may have highly reliable electrically insulating properties, which may lead to an electrical reliability of the package. Simultaneously, said porous colorant may color the encapsulant (preferably black or dark gray) which may improve legibility of laser marking formed on an exterior of a package encapsulant. Such a porous colorant may also provide advantages in terms of supporting a package stress test during which a significant color change may be prevented. Furthermore, an electrically insulating porous colorant may show excellent properties in terms of breakdown voltage and long-term low voltage stability. It may help to prevent corrosion, may function as an ion getter and may also act as an adhesion promoter in relation to constituents of a package which may come in direct physical contact with the encapsulant during encapsulation. Moreover, the time-dependent dielectric breakdown (TDDB) properties of an encapsulant having a porous colorant are beneficial.

According to a preferred embodiment, a mold compound-type encapsulant is provided with a colorant having tunable electrical conductivity and surface area for improved voltage stability and corrosion resistance. In particular, such a mold compound-type encapsulant may be embodied as a high voltage capable epoxy molding compound. In particular, the use of activated carbon as porous colorant in an electrically insulating epoxy molding compound has turned out as an excellent solution.

However, embodiments of the porous colorant are not limited to porous carbon materials. It may also be possible to use alternative non-conductive coloring agents, such as titanium dioxide (TiO₂).

Advantageously, a porous colorant (or a mixture of a porous colorant with a reduced amount of carbon black or the like) may be used as a constituent of an electrically insulating package encapsulant to provide color stability, ESD (electrostatic discharge) protection, legible laser marking, reduced potential of electrical treeing, etc.

A preferred embodiment may relate to the use of activated carbon as porous coloring agent in an epoxy molding compound. Activated carbon with a porous characteristics may provide several advantages compared to a conventionally used carbon black in an EMC:

On the one hand, such a porous colorant for a package encapsulant may be beneficial for high power devices and wide bandgap materials. Further advantageously, it may also enable package shrink and increased voltages.

Furthermore, such a porous colorant in a package encapsulant may offer particular advantages at high voltage conditions. High porosity is a main factor that reduces the material's intrinsic electric conductivity. For example, activated carbon formed with high porosity (i.e. surface area to mass or volume ratio) may show very strong electric insulation properties. Replacing carbon black with activated porous carbon (in particular entirely or partially) may maintain a black color in the EMC for color stability and case of laser marking. In addition, activated porous carbon (as an exemplary embodiment of a porous colorant) can significantly reduce any remaining electric conductivity by shortening the string of carbon black agglomerates in EMC. This may allow to reduce or even minimize the electrical treeing formation and EMC failure. A corresponding improvement may be achieved when it comes to tracking, since an increased comparative tracking index (CTI) may be obtained.

A further advantage of a porous colorant in a package encapsulant is its intrinsic protection against corrosion. A porous material has a high surface area to volume ratio. It can thus act as an efficient adsorbent to immobilize small organic contaminants, metals and ions (for instance chlorine ion adsorption at the surface of activated carbon via hydrogen bonding or Van der Waals forces). Therefore, activated porous carbon can act as an ion getter inside the EMC.

Further advantageously, no major change in the general EMC properties may occur, since the concentration of the porous color agent in an EMC may be relatively small, for example less than 1 weight percent in relation to the entire weight of the encapsulant. With activated porous carbon, being a black coloring agent, an EMC production line does not have to be changed significantly.

Hence, a preferred embodiment may relate to the use of activated porous carbon as a coloring agent in an epoxy resin-based mold compound (or based on silicone, bismaleimide or imide resin). Both hydrogen bonding and Van der Waals forces are primary modes of attraction in activated porous carbon. The mode of attraction may shift from hydrogen bonding to Van der Waals as the pH of a medium increases. The typical pH value of an EMC is between 3 and 8. To increase or even maximize anion adsorption (for instance Cl⁻, SO₄²⁻), the activated porous carbon may be provided with functional groups (for instance carboxylic acid, lactone, phenol, lactol, carboxylic anhydride, ether) capable of forming hydrogen bonding. A corresponding reaction may be as follows:

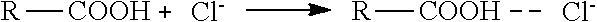

Thus, an activated porous carbon surface may be equipped with an R—COOH-group so as to be capable of capturing negative ions such as Cl⁻, thereby functioning as ion getter.

Preferably, the activated porous carbon may have a low electrical conductivity (which may be achievable via a high total pore volume), high chemisorption of oxygen (for forming carbon-oxygen complexes as defects which further reduce electric conductivity of the encapsulant), low graphitization degree and low nitrogen doping.

In another embodiment, an EMC is provided which contains a porous coloring agent (for instance porous titanium dioxide, or activated porous carbon) with no (or reduced concentration of) carbon black.

In still another embodiment, a porous colorant (for instance embodied as activated porous carbon) may be used for forming another kind of encapsulant than EMC, for example a gel (which may be used for instance as a silicone-based potting compound), etc.

In a preferred embodiment, an EMC with good electrical stability and corrosion resistance may be provided by equipping the EMC-type encapsulant with a porous colorant. This may eliminate or at least reduce the length of undesired conductive carbon strings in the EMC. Moreover, a porous colorant in an encapsulant may be advantageously used for reducing ionic mobility by immobilization or ion movement disruption. Further advantageously, a porous colorant may provide a very low electric conductivity, thereby contributing to the electric reliability of an encapsulated package. In a preferred embodiment, strictly no metal or modification may be present in the porous colorant, which may allow to reliably avoid any undesired increase of the electric conductivity and any undesired metal release to the EMC.

What concerns carbon black in the EMC, it may even be entirely absent or present in reduced concentration.

Activated porous carbon may have a structure similar to graphite, but with a highly porous structure with pores of different sizes. Activated porous carbon can have different cracks and crevices at the molecular level. Advantageously, activated porous carbon may have an internal surface area of up to 1500 m²/g, or more. Activated porous carbon may have a very high level of porosity, even down to the molecular level. Preferably, a porous colorant embodied as highly porous carbon may have an internal surface area of up to 1500 m²/g, or more. An appropriate range may be between 100 m²/g and 2000 m²/g, more particularly from 500 m²/g to 1750 m²/g, and preferred from 1000 m²/g to 1500 m²/g. More generally, an internal surface area per mass may be at least 100 m²/g or at least 200 m²/g.

A functional principle of embodiments with the mentioned high values of the internal surface area per mass may be that due to the high porosity of the porous carbon, the epoxy resin can incorporate the carbon with high porosity and may fill up the pores. That way, the resistivity of the final encapsulant may be far lower compared to non-porous carbon black. In non-porous carbon black, there is much less polymer in the same volume and thus electrical conductivity is higher, which reduces the risk for electrical fails under high voltage conditions.

When advantageously implementing a porous colorant such as a porous carbon with very high surface area, it may be further beneficial to carry out an additional surface activation of this carbon with high porosity. Advantageously, such an additional surface activation may change the chemical groups on the surface of the porous colorant. Such a surface treatment can change the structure in the pores and thus may lead to further improved properties. There are various surface treatments suitable for activated carbon. An example for such a surface treatment may work by an oxidation process as a first step, which can be done by corona treatment (preferably at high voltage and frequency), causing surface oxidation through O₃ and/or O₂ at the substrate by electric discharge. This oxidation can already lead to a further reduction in the electric conductivity, as the partly oxidized surface can increase surface resistivity of the porous carbon.

Other ways of treating the carbon can be with appropriate chemicals (such as H₂O₂, NH₃) which may lead to different functional groups on the surface, such as —OH, —NH₂ groups, etc. Other functionalities can be achieved as well, for instance by using chemical groups such as —SH, ═O, —COOH, COOR, COONH₂,-epoxy, etc.

All these surface treatments can be used to further reduce the conductivity of the activated porous carbon as well as improving the adhesion between the resin and the carbon particles. In addition, the change of surface chemistry can also change other properties such as the pH value of the surrounding, which can influence the material properties.

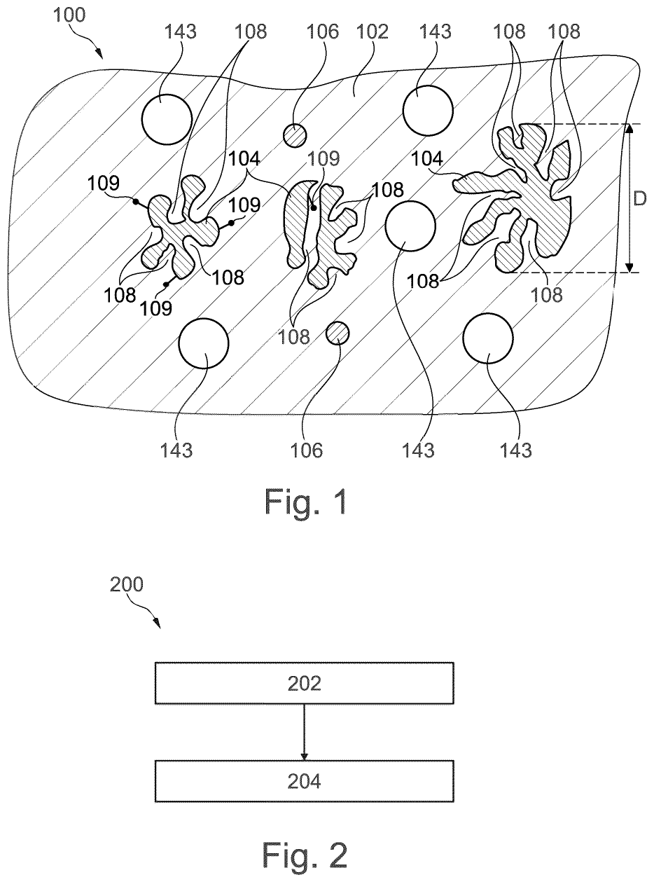

FIG. 1 illustrates an encapsulant 100 according to an exemplary embodiment.

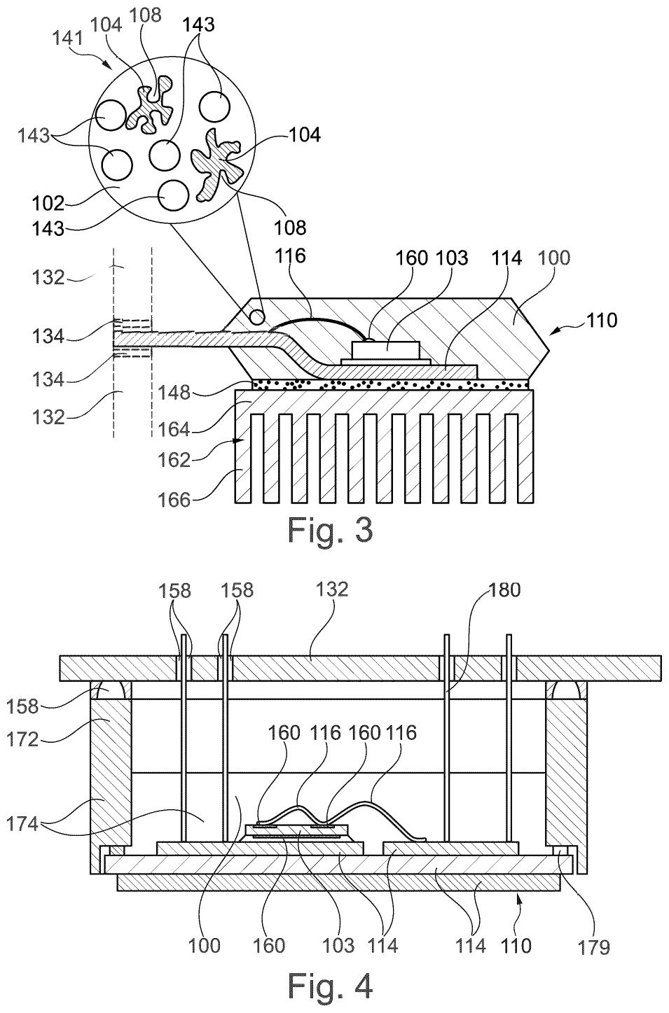

The schematically illustrated encapsulant 100 is configured for encapsulating an electronic package 110, such as the one shown in FIG. 3 and FIG. 4.

As shown, the encapsulant 100 comprises an electrically insulating matrix material 102. For a mold compound-type encapsulant 100 as used for the package 110 of FIG. 3, the matrix material 102 may comprise an epoxy resin. For a potting-type encapsulant 100 as used for the package 110 of FIG. 4, the matrix material 102 may comprise silicone.

Moreover, the encapsulant 100 may comprise filler particles 143 for fine-tuning the physical properties of the encapsulant 100. For example, the filler particles 143 may be aluminum nitride particles for enhancing thermal conductivity.

Apart from this, one or a plurality of further additives (not shown in FIG. 1) may be added to the encapsulant 100 for further adjusting its physical properties and for providing a dedicated functionality. Added additives may comprise a voltage stabilizer, an antioxidant, an ultraviolet (UV) absorber, an adhesion promoter, low stress additives, etc.

Advantageously, a porous colorant 104 may be mixed into the matrix material 102. For instance, an amount of the porous colorant 104 is 1 weight percent, in relation to the entire weight of the encapsulant 100. An electric conductivity of the porous colorant 104 may be for example 10⁻⁴ S/cm. This provides the encapsulant 100 with a pronounced dark color and reliable electrically insulating properties. As can be seen in FIG. 1, the porous colorant 100 comprises a large number of pores 108 which significantly increase the exterior surface area of the particles of the porous colorant 104. Preferably, the porous colorant 104 has a surface area to mass ratio of at least 100 m²/g, most preferably in a range from 1000 m²/g to 1500 m²/g.

Individual particles of the porous colorant 104 may have a maximum size D in a range from 0.1 μm to 100 μm, for instance in a range from 5 μm to 50 μm. The porous colorant 104 may preferably comprise porous activated carbon. Additionally or alternatively, porous titanium dioxide may form or may form part of the porous colorant 104.

Optionally, the encapsulant 100 may additionally comprise an electrically conductive colorant of limited amount, such as carbon black 106. Preferably, the amount of carbon black 106 in encapsulant 100 is strictly limited in order to avoid deterioration of the reliable electric insulating properties of encapsulant 100. However, a small amount of carbon black 106 may be advantageous in certain scenarios, since it may improve the color intensity of encapsulant 100. For instance, the entire colorant may be composed of 80 weight percent porous colorant 104 (here embodied as activated porous carbon) and 20 weight percent of non-porous colorant (here embodied as carbon black 106), both related to the entire weight of the overall colorant.

Advantageously, the porous colorant 104 embodied as activated porous carbon is configured as ion getter. For this purpose, at least part of the particles of the porous colorant 104 may be equipped with at least one ion adsorbing group 109, shown schematically in FIG. 1. Examples for appropriate ion adsorbing groups 109 are a carboxylic acid, a lactone, a phenol, a lactol, and/or a carboxylic anhydride. Advantageously, the porous colorant 104 may be configured for forming carbon-oxygen complexes when in use. Furthermore, the porous colorant 104 may be provided with a low nitrogen doping and with a low graphitization degree. All these measures may contribute additionally to a strong electric isolation of the porous colorant 104 and thus to the excellent electric reliability of a package 110 comprising that encapsulant 100.

For fine-tuning the mentioned properties of the porous colorant 104, the porous colorant 104 may be subjecting to an additional surface activating process for changing chemical groups (such as the at least one ion adsorbing group 109) on its surface. For example, treating the porous colorant 104 may encompass steam processing, oxidizing, corona treatment and/or a chemical treatment. It may be particularly advantageous that treating the porous colorant 104 is accomplished selectively for reducing its electric conductivity and/or for increasing adhesion properties with respect to the constituents of an assigned package 110 (see FIG. 3 and FIG. 4.

FIG. 2 illustrates a flowchart 200 of a method of manufacturing an encapsulant 100 for an electronic package 110 according to an exemplary embodiment. The reference signs used for the following description of said manufacturing method relate to the embodiments of FIG. 1 and FIG. 3.

Referring to a block 202, the method comprises providing a matrix material 102.

Referring to a block 204, the method furthermore comprises inserting a porous colorant 104 in the matrix material 102.

FIG. 3 illustrates a cross-sectional view of a molded package 110 according to an exemplary embodiment.

The semiconductor package 110 is mounted on a mounting structure 132, here embodied as printed circuit board.

The mounting structure 132 comprises an electric contact 134 embodied as a plating in a through hole of the mounting structure 132. When the semiconductor package 110 is mounted on the mounting structure 132, a semiconductor component 103 of the semiconductor package 110 is electrically connected to the electric contact 134 via an electrically conductive carrier 114, here embodied as a leadframe made of copper.

The semiconductor package 110 thus comprises the electrically conductive carrier 114, the semiconductor component 103 (which is here embodied as a power semiconductor chip) mounted on the carrier 114, and an encapsulant 100 encapsulating part of the carrier 114 and the semiconductor component 103.

As can be taken from FIG. 3, a pad 160 on an upper main surface of the semiconductor component 103 is electrically coupled to the carrier 114 via a bond wire as electrically conductive connection element 116. Alternatively, a clip may be used as electrically conductive connection element 116 (not shown).

In particular, the carrier 114 may comprise different leads, that are going out of the encapsulant 110 of the package 110. The backside of the semiconductor component 103 (such as a die) is connected to one part of the carrier 114, while the electrically conductive connection element 116 (such as a bond wire) is not connected to the same lead. Instead, each lead may be separately connected to the carrier 114 at different contact holes.

During operation of the power semiconductor package 110, the power semiconductor chip in form of the semiconductor component 103 generates a considerable amount of heat. At the same time, it shall be ensured that any undesired current flow between a bottom surface of the semiconductor package 110 and an environment is reliably avoided.

For ensuring electrical insulation of the semiconductor component 103 and removing heat from an interior of the semiconductor component 103 towards an environment, an electrically insulating and thermally conductive interface structure 148 may be provided which covers an exposed surface portion of the carrier 114 and a connected surface portion of the encapsulant 100 at the bottom of the semiconductor package 110. The electrically insulating property of the interface structure 148 prevents undesired current flow even in the presence of high voltages between an interior and an exterior of the semiconductor package 110. The thermally conductive property of the interface structure 148 promotes a removal of heat from the semiconductor component 103, via the electrically conductive carrier 114 (for instance of thermally conductive copper), through the interface structure 148 and towards a heat dissipation body 162. The heat dissipation body 162, which may be made of a highly thermally conductive material such as copper or aluminum, has a base body 164 directly connected to the interface structure 148 and has a plurality of cooling fins 166 extending from the base body 164 and in parallel to one another so as to remove the heat towards the environment.

Construction and function of encapsulant 100 can be for instance as illustrated in and described referring to FIG. 1. However, a detail 141 of FIG. 3 shows a slightly modified encapsulant 100 and will be explained in the following in further detail. The encapsulant 100 of FIG. 3 is a mold compound-type composite. As shown in detail 141 of FIG. 3, composite encapsulant 100 comprises a matrix 102 of epoxy resin and filler particles 143 in the matrix 102. Some or all of the filler particles 143 may be solid spheres. Advantageously, particles of a porous colorant 104 each having multiple pores are included in encapsulant 100. In the embodiment of FIG. 3, the encapsulant 100 is completely free of other colorants than the porous colorant 104, in particular is free of carbon black (see reference sign 106 in FIG. 1). This may ensure a highly reliable electric insulation of the encapsulant 100 of FIG. 3.

The illustrated semiconductor package encapsulant 100 encapsulates the semiconductor component 103 with its metallic pad 160, leadframe-type metallic chip carrier 114, and bond wire-type electrically conductive connection element 116 partially or entirely. Filler particles 143 of the semiconductor package encapsulant 100 may enhance thermal conductivity and may be made for instance of aluminum oxide and/or boron nitride. The porous colorant 104 provides the encapsulant 100 of FIG. 3 with a dark color and contributes, together with the electrically insulating matrix material 102, significantly to the strong electric insulating properties of the encapsulant 100.

FIG. 4 illustrates a cross-sectional view of a semiconductor package 110 with a semiconductor component 103 encapsulated by potting according to another exemplary embodiment. Thus, FIG. 4 illustrates a semiconductor package encapsulant 100 embodied as potting compound. The semiconductor package 110 of FIG. 4 can be a power package.

The shown semiconductor package 110 is mounted with a mounting structure 132 being embodied as printed circuit board (PCB). Semiconductor package 110 is mounted at its mounting interface on the mounting structure 132 with a sealing 158 in between. Preferably, the gas flow-inhibiting sealing 158 may establish a gas flow-tight connection between semiconductor package 110 and mounting structure 132.

The semiconductor package 110 comprises a semiconductor component 103, such as a power semiconductor chip, for instance comprising a field effect transistor (FET). Semiconductor component 103 has metallic pads 160.

An enclosure 174 encloses the semiconductor component 103 and defines a module interface at which the semiconductor package 110 is to be mounted on the mounting structure 132. In the shown embodiment, the enclosure 174 is composed of two parts. A first or interior part of the enclosure 174 is embodied as a soft encapsulant 100 (for instance made of a silicone gel and comprising filler particles 143) which directly encapsulates the semiconductor component 103 with physical contact, for instance is applied by potting. A second or exterior part of the enclosure 174 is embodied as a rigid casing or housing 172 which may be made of plastic and accommodates the semiconductor component 103 and the soft encapsulant 100.

Furthermore, vertically extending electrically conductive needles 180 may be provided which electrically couple the semiconductor component 103 and the carrier 114 with an exterior of the semiconductor package 110, more precisely with the mounting structure 132. The needles 180 may also extend through the mounting structure 132. More precisely, bottom ends (according to FIG. 4) of the needles 180 may be connected at an upper main surface of the carrier 114. Furthermore, top ends (according to FIG. 4) of the needles 180 may be guided through the mounting structure 132 and may even protrude beyond the upper side of the mounting structure 132.

As shown as well in FIG. 4, the semiconductor package 110 comprises carrier 114 carrying the semiconductor component 103. The semiconductor component 103 may be soldered on the carrier 114. In the shown embodiment, the carrier 114 comprises a central thermally conductive and electrically insulating plate (for instance made of a ceramic) covered on both opposing main surfaces thereof with a respective electrically conductive layer (such as a continuous or patterned copper or aluminium layer). For instance, the carrier 114 may be a Direct Copper Bonding (DCB) substrate or a Direct Aluminium Bonding (DAB) substrate. It is also possible to embody the carrier 114 as Active Metal Brazing (AMB) substrate. The semiconductor component 103 is mounted on the top-sided electrically conductive layer. The bottom-sided electrically conductive layer may be connected to a heat sink (not shown) for promoting heat removal out of the semiconductor package 110 during operation thereof.

Thus, the outer layer of the carrier 114 is configured for mounting a heat sink (not shown) thereon in order to efficiently remove heat out of the semiconductor package 110, which is generated by semiconductor component 103 mounted on the interior layer of the carrier 114. Said semiconductor component 103 may, for instance, be a power semiconductor chip. Electric connection of the semiconductor component 103 can be accomplished by the carrier 114 (in particular by the inner electrically conductive layer thereof) and by electrically conductive connection elements 116 connecting the carrier 114 with the pads 160 on an upper main surface of the semiconductor component 103. Said electrically conductive connection elements 116 are here embodied as bond wires, but may alternatively be bond ribbons or clips.

As shown as well, the semiconductor component 103 mounted on the carrier 114 is enclosed within the enclosure 174, which is composed of soft encapsulant 100 and wall of housing 172.

The semiconductor package 110 can further comprise a further gas flow-inhibiting sealing 179 between the carrier 114 and the housing 172 of the enclosure 174.

The electrically conductive needles 180 extend from the carrier 114 through the encapsulant 100 and through sealing 158 at the module interface at which the semiconductor package 110 faces mounting structure 132. For instance, the semiconductor package 110 and the mounting structure 132 may be connected by screwing, soldering, sintering, gluing and/or mechanically pressing.

By embodying the potting-type encapsulant 100 in a corresponding way as described above referring to FIG. 1 or FIG. 3 (however preferably based on silicone gel as matrix 102, whereas also epoxy resin is possible), a pronounced and defined colouring as well as a high electric reliability may be achieved.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An encapsulant for an electronic package, wherein the encapsulant comprises:
an electrically insulating matrix material; and
a porous colorant in the matrix material.

2. The encapsulant according to claim 1, wherein the matrix material comprises an epoxy resin, silicone, a bismaleimide and/or an imide.

3. The encapsulant according to claim 1, wherein the porous colorant comprises porous activated carbon.

4. The encapsulant according to claim 1, wherein the porous colorant comprises porous titanium dioxide.

5. The encapsulant according to claim 1, wherein the encapsulant additionally comprises carbon black and/or crystalline petroleum coke.

6. The encapsulant according to claim 5, wherein a ratio between an amount, in weight percent, of the porous colorant and an amount, in weight percent, of the carbon black and/or the crystalline petroleum coke is in a range from 1:4 to 4:1.

7. The encapsulant according to claim 1, wherein the encapsulant is free of carbon black and/or is free of crystalline petroleum coke.

8. The encapsulant according to claim 1, wherein the porous colorant is configured as ion getter.

9. The encapsulant according to claim 1, wherein the porous colorant comprises at least one ion adsorbing group, in particular a carboxylic acid, a lactone, a phenol, a lactol, and/or a carboxylic anhydride.

10. The encapsulant according to claim 1, wherein an amount of the porous colorant is at least 0.5 weight percent, in relation to the entire weight of the encapsulant.

11. The encapsulant according to claim 1, wherein the porous colorant has an electric conductivity of not more than 10⁻³ S/cm.

12. The encapsulant according to claim 1, wherein the porous colorant is configured for forming carbon-oxygen complexes when in use.

13. The encapsulant according to claim 1, wherein the porous colorant has a surface area to mass ratio of at least 100 m²/g.

14. The encapsulant according to claim 1, comprising one of the following features:
configured as a mold compound, in particular as an epoxy-based mold compound;
configured as a potting compound, in particular as a silicone gel-based compound.

15. The encapsulant according to claim 1, wherein particles of the porous colorant have a size in a range from 0.1 μm to 100 μm.

16. A package, comprising:
a carrier;
an electronic component mounted on the carrier; and
an encapsulant according to claim 1 at least partially encapsulating the electronic component and the carrier.

17. The package according to claim 16, wherein the electronic component is a semiconductor power chip.

18. The package according to claim 16, wherein the package is a power package.

19. A method of manufacturing an encapsulant for an electronic package, wherein the method comprises:
providing an electrically insulating matrix material; and
inserting a porous colorant in the matrix material.

20. The method according to claim 19, comprising at least one of the following features:
wherein the method comprises subjecting the porous colorant to an additional surface activating process for changing chemical groups on its surface;
wherein the method comprises treating the porous colorant by steam processing, oxidizing, corona treatment and/or a chemical treatment;
wherein the method comprises treating the porous colorant for reducing its electric conductivity.
